(19) United States
(12) Patent Application Publication
(10) Pub. No.: US 2015/0233992 A1
(43) Pub. Date: Aug. 20, 2015

(54) SYSTEM AND METHOD FOR ANALYZING ARRANGEMENT OF VEHICLE AND BUILDING WIRE HARNESSES FOR EMI

(71) Applicant: AIRBUS ENGINEERING CENTRE INDIA, Bangalore (IN)

(72) Inventors: Abhay Singh, Bangalore (IN); Srinivasan Bhaskaran, Bangalore (IN); Vishal Narayan, Bangalore (IN); Ramakrishna Katakam, Bangalore (IN); Mahadevan Shanmugam, Bangalore (IN)

(21) Appl. No.: 14/421,846

(22) PCT Filed: Aug. 8, 2013
(86) PCT No.: PCT/IN2013/000488

§ 371 Date: Feb. 16, 2015

(30) Foreign Application Priority Data
Aug. 17, 2012 (IN) 3396/CHE/2012

(51) Int. Cl. G01R 31/00; G06F 17/50; G01B 21/16

(52) U.S. Cl. CPC G01R 31/001; G01B 21/16; G06F 17/50

(57) ABSTRACT

A system and method for analyzing arrangement of vehicle and building wire harnesses for electromagnetic interference (EMI) are disclosed. In one embodiment, at least design data of a first wire harness and a second wire harness and associated electrical structure of the vehicle or building are received. Further, a plurality of cutting planes are applied to intersect at least the first wire harness and the second wire harness and the associated electrical structure based on the design data. Furthermore, a respective set of cutting points are identified for each of the plurality of cutting planes. The respective set of cutting points includes locations where a respective cutting plane intersects at least the first wire harness and the second wire harness and the associated electrical structure. In addition, a segregation distance is measured between each respective set of cutting points.

### FIELD OF TECHNOLOGY

Embodiments of the present subject matter relate to design of wire harnesses in a vehicle or building. More particularly, the embodiments of the present subject matter relate to analyzing arrangement of vehicle and building wire harnesses and its effect on electromagnetic interference (EMI).

### BACKGROUND

In designing vehicle electrical structure networks, for example aircraft, automobile, spacecraft and construction machinery electrical structure networks, wire harnesses are often placed within close proximity of one another. If these wire harnesses are placed within a certain distance of each other, electromagnetic interference (EMI) can develop and may lead to alterations of signals within the structures. For example, a close arrangement of wire harnesses may lead to EMI and produce a complete signal failure within the wire harnesses, thus causing a short circuit within a vehicle incorporating the wire harnesses. Further, if the vehicle structures are made of non-metallic materials, such as carbon-fiber composite, the above problem can compound the EMI problem resulting from close proximity of the wire harnesses, as it requires a minimum distance between wire harnesses.

Existing techniques for analyzing the wire harnesses in the vehicle structures for EMI require manually measuring the distance between wire harnesses in a design environment using the creation of geometric data derived from the vehicle structures. Such manual measurements can vary in complexity and can be very time consuming, depending on the complication of the geometry and variation of paths in the vehicle electrical structures themselves.

### SUMMARY

A system and method for analyzing arrangement of vehicle and building wire harnesses for electromagnetic interference (EMI) are disclosed. According to one aspect of the present subject matter, at least design data of a first wire harness and a second wire harness and associated electrical structure of the vehicle or building are received. Further, a plurality of cutting planes are applied to intersect at least the first wire harness and the second wire harness and the associated electrical structure based on the design data. Furthermore, a respective set of cutting points are identified for each of the plurality of cutting planes. The respective set of cutting points includes locations where a respective cutting plane intersects at least the first wire harness and the second wire harness and the associated electrical structure. In addition, a segregation distance is measured between each respective set of cutting points.

Also, one or more electrical structural network (ESN) distances between the associated electrical structure and the first wire harness and the second wire harness are measured for each respective set of cutting points. Moreover, the segregation distance and ESN distances for each respective set of cutting points are compared to at least one predefined segregation distance value and predefined ESN distance value, respectively. Further, it is verified whether the segregation distance and the ESN distances for each respective set of cutting points is higher than the at least one predefined segregation distance value and predefined ESN value, respectively, for EMI design compliance.

According to another aspect of the present subject matter, a vehicle and building wire harness arrangement analysis system includes a processor and memory coupled to the processor. Further, the memory includes a vehicle and building wire harness arrangement analysis tool. In one embodiment, the vehicle and building wire harness arrangement analysis tool has instructions to receive at least design data of the first wire harness and the second wire harness and associated electrical structure of the vehicle or building. Further, the vehicle and building wire harness arrangement analysis tool applies the plurality of cutting planes to intersect at least the first wire harness and the second wire harness and the associated electrical structure based on the design data. Furthermore, the vehicle and building wire harness arrangement analysis tool identifies the respective set of cutting points for each of the plurality of cutting planes. The respective set of cutting points includes locations where a respective cutting plane intersects at least the first wire harness and the second wire harness and the associated electrical structure. In addition, the vehicle and building wire harness arrangement analysis tool measures the segregation distance between each respective set of cutting points.

Also in this embodiment, the vehicle and building wire harness arrangement analysis tool measures one or more ESN distances between the associated electrical structure and the first wire harness and the second wire harness for each respective set of cutting points. Moreover, the vehicle and building wire harness arrangement analysis tool compares the segregation distance and ESN distances for each respective set of cutting points to at least one predefined segregation distance value and predefined ESN distance value, respectively. In addition, the vehicle and building wire harness arrangement analysis tool verifies whether the segregation distance and the ESN distances for each respective set of cutting points is higher than the at least one predefined segregation distance value and the predefined ESN value, respectively, for EMI design compliance.

According to yet another aspect of the present subject matter, a non-transitory computer-readable storage medium for analyzing arrangement of vehicle and building wire harnesses for EMI having instructions that, when executed by a computing device, causes the computing device to perform the method described above.

The system and method disclosed herein may be implemented in any means for achieving various aspects. Other features will be apparent from the accompanying drawings and from the detailed description that follow.

### BRIEF DESCRIPTION OF THE DRAWINGS

Various embodiments are described herein with reference to the drawings, wherein:

FIG. 1 illustrates a flow diagram of an exemplary method for analyzing arrangement of vehicle and building wire harnesses for electromagnetic interference (EMI), according to one embodiment;

FIG. 2 illustrates a flow diagram of wire harness selection method, according to one embodiment;

FIG. 3 illustrates a flow diagram of segregation analysis method, according to one embodiment;

FIG. 4 illustrates a flow diagram of segregation distances verification method, according to one embodiment;

FIG. 5 is a schematic diagram illustrating two selected wire harnesses and associated electrical structures of the vehicle or building, according to one embodiment;

FIG. 6 is schematic diagram illustrating segregation measurements between the two selected wire harnesses and electrical structure network (ESN) distances, using the process described with reference to FIGS. 1 and 3, according to one embodiment;

FIG. 7 is a screenshot illustrating segregation distances obtained between the two selected wire harnesses after performing the methods described with reference to FIGS. 1 and 3. according to one embodiment; and

FIG. 8 illustrates a vehicle and building wire harness arrangement analysis system including a vehicle and building wire harness arrangement analysis tool for analyzing arrangement of vehicle and building wire harnesses for EMI, using the process described with reference to FIGS. 1 to 4, according to one embodiment.

The drawings described herein are for illustration purposes only and are not intended to limit the scope of the present disclosure in any way.

### DETAILED DESCRIPTION

A system and method for analyzing arrangement of vehicle and building wire harnesses for electromagnetic interference (EMI) are disclosed. In the following detailed description of the embodiments of the present subject matter, references are made to the accompanying drawings that form a part hereof, and in which are shown by way of illustration specific embodiments in which the present subject matter may be practiced. These embodiments are described in sufficient detail to enable those skilled in the art to practice the present subject matter, and it is to be understood that other embodiments may be utilized and that changes may be made without departing from the scope of the present subject matter. The following detailed description is, therefore, not to be taken in a limiting sense, and the scope of the present subject matter is defined by the appended claims.

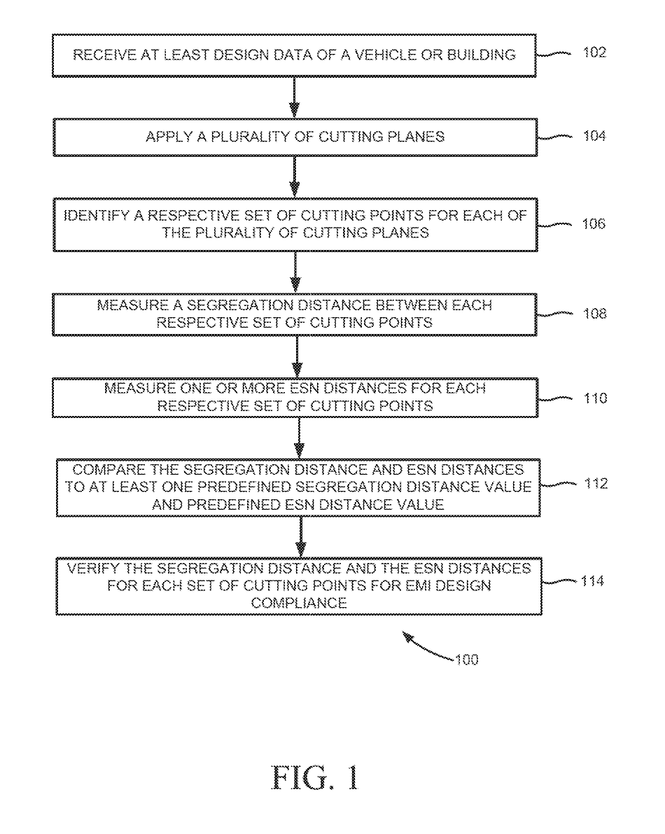

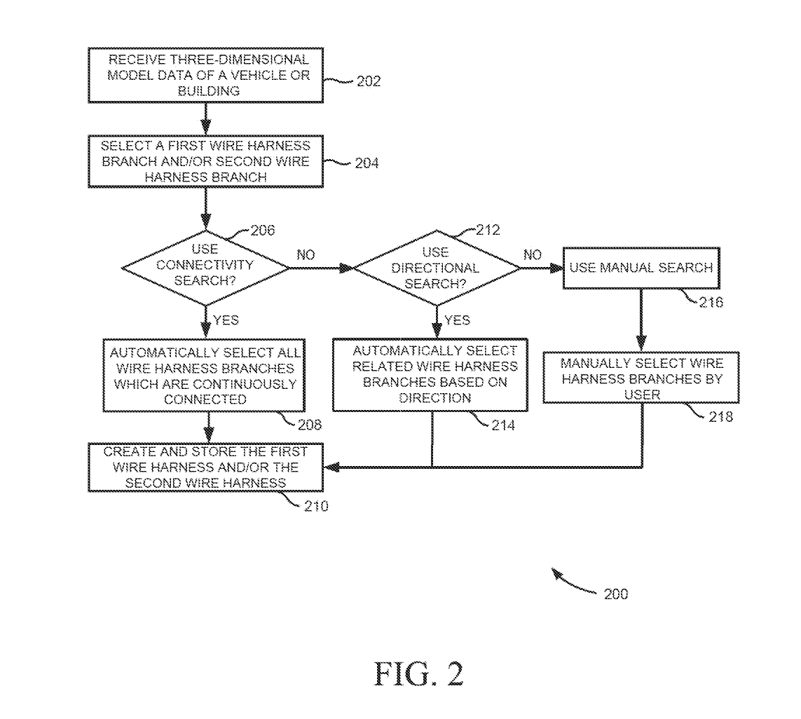

FIG. 1 illustrates a flow diagram 100 of an exemplary method for analyzing arrangement of vehicle and building wire harnesses for EMI, according to one embodiment. At block 102, at least design data of a first wire harness and a second wire harness and associated electrical structure of the vehicle or building are received. For example, the first wire harness is a victim harness which has been affected by the EMI effects of the second harness (affecting harness). The design data is computer aided design (CAD) data. Exemplary vehicle includes an automobile, a construction machine or a spacecraft. In one embodiment, three-dimensional model data of the vehicle or building is received. Further, the first wire harness and/or the second wire harness are created using a connectivity search of the model data. In creating the first wire harness and/or the second wire harness using the connectivity search of the model data, a first wire harness branch and/or second wire harness branch is selected. Further, all wire harness branches which are continuously connected to the first wire harness branch and/or the second wire harness branch are automatically selected. This is explained in more detail with reference to FIG. 2.

In another embodiment, the three-dimensional model data of the vehicle or building is received. Further, the first wire harness and/or the second wire harness are created using a directional search of the model data. In creating the first wire harness and/or the second wire harness using the directional search of the model data, a first wire harness branch and/or a second wire harness branch is selected. Further, one or more wire harness branches for which EMI effects with the first wire harness branch and/or second wire harness branch needs to be analyzed and a deviation angle formed with the first wire harness branch and/or second wire harness branch is of a value lower than a predefined set angle are automatically selected. This is explained in more detail with reference to FIG. 2.

In yet another embodiment, the three-dimensional model data of the vehicle or building is received. Further, the first wire harness and/or the second wire harness are created using a manual search of the model data. For example, a user manually selects associated wire harness branches individually. This is explained in more detail with reference to FIG. 2.

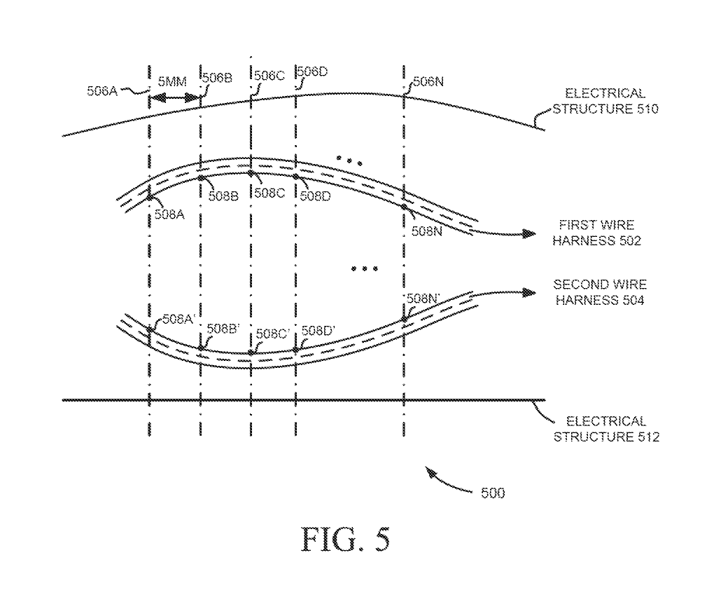

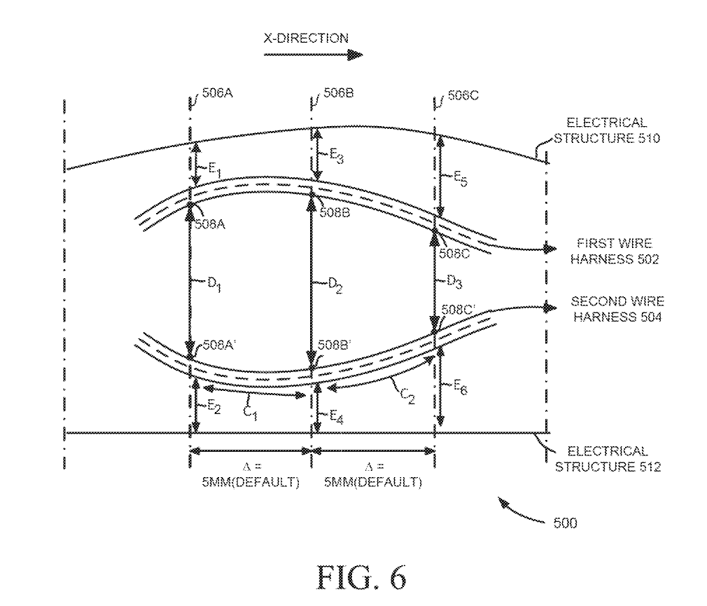

At block 104, a plurality of cutting planes are applied to intersect at least the first wire harness and the second wire harness and the associated electrical structure based on the design data. The plurality of cutting planes are applied to perpendicularly intersect at least the first wire harness and the second wire harness and the associated electrical structure based on the design data. In one embodiment, the plurality of cutting planes intersects at least the first wire harness and the second wire harness according to a predefined resolution. The predefined resolution is based on parameters, such as direction of wire harness and curvature of the wire harness. This is explained in more detail with reference to FIGS. 5 and 6.

At bock 106, a respective set of cutting points for each of the plurality of cutting planes are identified. The respective set of cutting points includes locations where a respective cutting plane intersects at least the first wire harness and the second wire harness and the associated electrical structure. At block 108, a segregation distance is measured between each respective set of cutting points. This is explained in more detail with reference to FIGS. 5 and 6.

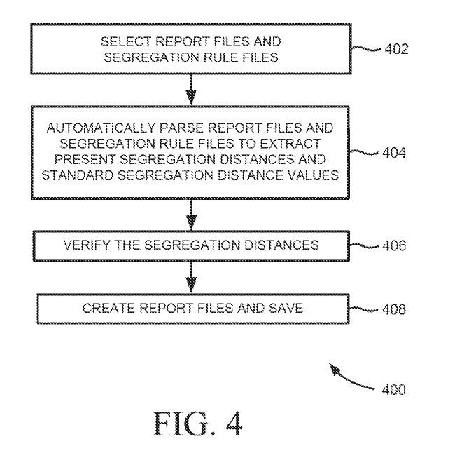

At block 110, one or more electrical structural network (ESN) distances between the associated electrical structure and the first wire harness and the second wire harness are measured for each respective set of cutting points. This is explained in more detail with reference to FIG. 6. At block 112, the segregation distance and ESN distances for each respective set of cutting points are compared to at least one predefined segregation distance value and predefined ESN distance value, respectively. At block 114, it is verified whether the segregation distance and the ESN distances for each respective set of cutting points is higher than the at least one predefined segregation distance value and the predefined ESN value, respectively for EMI design compliance. This is explained in more detail with reference to FIG. 4.

Referring now to FIG. 2, which illustrates a flow diagram 200 of wire harness selection method, according to one embodiment. At block 202, a three-dimensional model data of a vehicle or building is received. Exemplary vehicle includes an aircraft, an automobile, a construction machine and a spacecraft. At block 204, a first wire harness and/or a second wire harness branch is selected. At block 206, it is determined whether connectivity search of the model data is used. If it is determined that connectivity search of the model data is used, then, at bock 208, all wire harness branches which are continuously connected are automatically selected. In one embodiment, a tolerance is created at the end of the selected first wire harness and/or second wire harness branch using a bubble. A start point of a wire harness branch which lies within the created tolerance is considered to be connected to the selected first wire harness and/or second wire harness branch.

Referring back to block 206, if it is determined that connectivity search of the model data is not used, then, at block 212, it is determined whether directional search is used. If it is determined that directional search of the model data is used, then, at block 214, related wire harness branches are automatically selected based on direction. For example, one or more wire harness branches for which EMI effects with the first wire harness and/or second wire harness branch needs to be analyzed are automatically selected. In one embodiment, wire harness branches which forms a deviation angle of a value lower than a predefined set angle with the first wire harness and/or second wire harness branch are selected. For example, a wire harness branch whose start and end points lie within the deviation angle are selected.

Referring back to block 212, if it is determined that directional search of the model data is not used, then, at block 216, manual search is used. At block 218, wire harness branches are manually selected. In one embodiment, a user manually selects associated wire harness branches individually. At block 210, the first wire harness and/or second wire harness are created and stored. In one embodiment, the first wire harness and/or second wire harness is stored in the form of CAD data.

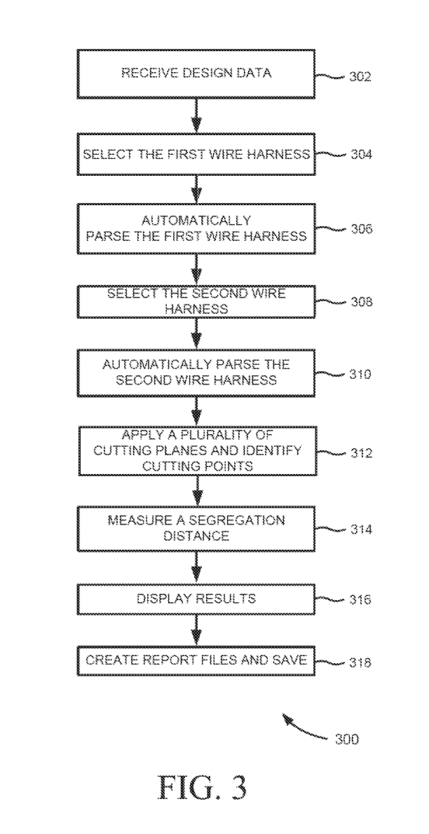

Referring now to FIG. 3, which illustrates a flow diagram 300 of segregation analysis method, according to one embodiment. At block 302, design data of a first wire harness and a second wire harness and associated electrical structure of the vehicle or building are received. This is explained in more detail with reference to FIG. 2. At block 304, the first wire harness is selected. At block 306, the first wire harness is automatically parsed.

At block 308, the second wire harness is selected. At block 310, the second wire harness is automatically parsed. At block 312, a plurality of cutting planes is applied and cutting points are identified. In one embodiment, the plurality of cutting planes are applied to intersect at least the first wire harness and the second wire harness and the associated electrical structure based on the design data. Further, a respective set of cutting points are identified for each of the plurality of cutting planes. The respective set of cutting points includes locations where a respective cutting plane intersects at least the first wire harness and the second wire harness and the associated electrical structure.

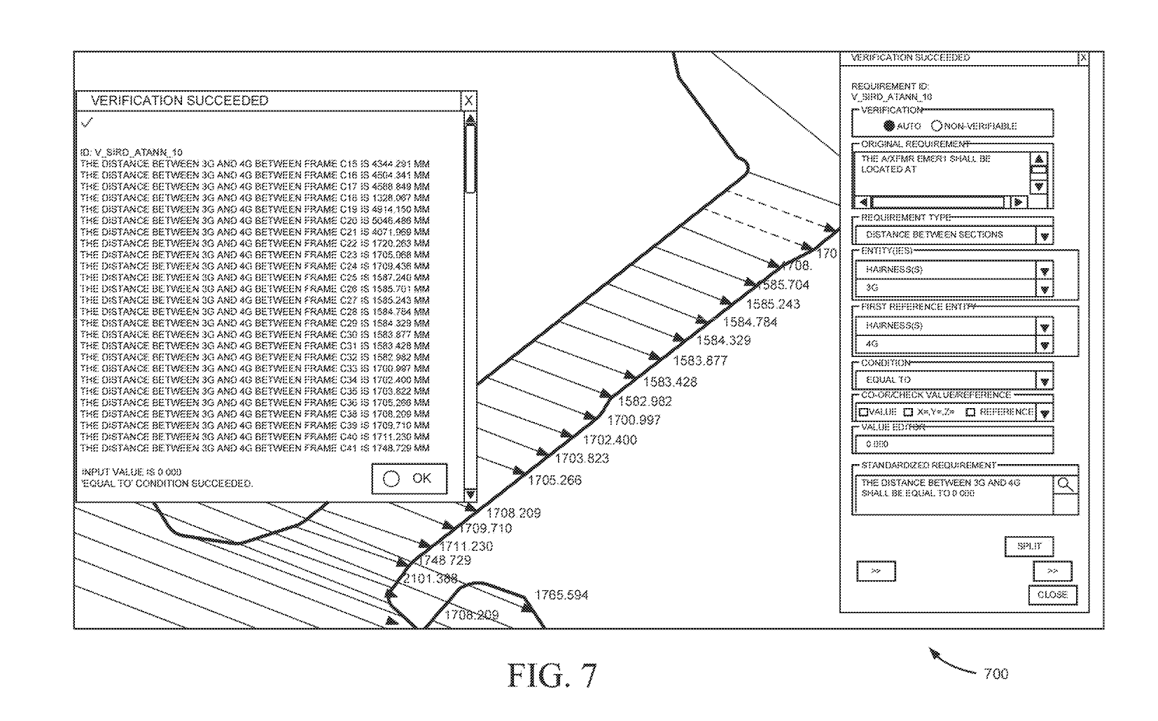

At block 314, segregation distance is measured between respective set of cutting points. This is explained in more detail with reference to FIGS. 5 and 6. At block 316, results are displayed. The results, include the measured segregation distances. This is explained in more detail with reference to FIG. 7. At block 318, report files are created and saved.

Referring now to FIG. 4, which illustrates a flow diagram 400 of segregation distances verification method according to one embodiment. At block 402, report files and segregation rule files are selected. The creation of the report files is explained in more detail with reference to FIG. 3. At block 404, the report files and segregation rule files are automatically parsed to extract present segregation distances and standard segregation distance values. At block 406, the segregation distances are verified. In one embodiment, the segregation distance for each set of cutting points is compared to at least one predefined segregations distance value. Further, it is verified whether the segregation distance for each set of cutting points is higher than the at least one predefined segregation distance value. At block 408, report files are created and stored.

Referring now to FIG. 5, which illustrates a schematic diagram 500 of two selected wire harnesses and associated electrical structure of a vehicle or building, according to one embodiment. Particularly, FIG. 5 illustrates a first wire harness 502, a second wire harness 504 and associated electrical structures 510 and 512. In one embodiment, design data of the first wire harness 502, the second wire harness 504 and the associated electrical structures 510 and 512 of a vehicle or building are received. The design data is CAD data. This is explained in more detail with reference to FIG. 2.

In operation, a plurality of cutting planes 506A-N is applied to intersect the first wire harness 502 and the second wire harness 504 and the associated electrical structures 510 and 512. In one embodiment, the plurality of cutting planes 506A-N is applied to perpendicularly intersect the first wire harness 502 and the second wire harness 504 and the associated electrical structures 510 and 512. In one embodiment, the plurality of cutting planes 506A-N is perpendicular to the average direction of the first wire harness 502 and the second wire harness 504. For example, the plurality of cutting planes 506A-N intersect the first wire harness 502 and the second wire harness 504 according to a predefined resolution. The predefined resolution is based on parameters, such as direction of wire harness and curvature of wire harness.

Further in operation, a respective set of cutting points 508A, 508A′ to 508N, 508N′ are identified for each of the plurality of cutting planes 506A-N. The respective set of cutting points 508A, 508A′ to 508N, 508N′ includes locations where a respective set of cutting planes 506A-N intersects the first wire harness 502 and the second wire harness 504 and the electrical structures 510 and 512. For example, cutting points 508A and 508A′ includes locations where cutting plane 506A intersects the first wire harness 502 and the second wire harness 504, respectively. Furthermore in operation, segregation distance between each respective set of cutting points 508A, 508A′ to 508N, 508N′ are measured. This is explained in more detail with reference to FIG. 6.

Referring now to FIG. 6, which illustrates the schematic diagram 500 for segregation measurements between the two selected wire harnesses and ESN distances, using the process described with reference to FIGS. 1 and 3, according to one embodiment. Particularly, FIG. 6 illustrates the first wire harness 502, the second wire harness 504 and the associated electrical structures 510 and 512. Further, FIG. 6 illustrates the cutting points 508A, 508A′ to 508C, 508C′ and the plurality of cutting planes 506A-C. This is explained in more detail with reference to FIG. 5.

In operation, segregation distances D₁-D₃ between each respective set of cutting points 508A, 508A′ to 508C, 508C′ is measured. For example, segregation distance D₁ is measured between cutting points 508A and 508A′. Further in operation, one or more ESN distances E₁-E₆ are measured between the electrical structures 510 and 512 and the first wire harness 502 and the second wire harness 504 for each respectively set of cutting points 508A, 508A′ to 508C, 508C′. For example, the ESN distances E₁ is measured between the electrical structure 510 and the first wire harness 502 and the ESN distance E₂ is measure between the electrical structure 512 and the second wire harness 504. Furthermore in operation, coupling distances C₁ and C₂ are measured between the cutting planes 506A-C. For example, the coupling distance C₁ is measured between the cutting planes 506A and 506B.

In addition in operation, the segregation distances D₁-D₃ and the ESN distances E₁-E₆ for each respective set of cutting points 508A, 508A′ to 508C, 508C′ are compared to at least one predefined segregation distance value and predefined ESN distance value. Also in operation, it is verified whether the segregation distances D₁-D₃ and the ESN distances E₁-E₆ for each respective set of cutting points 508A, 508A′ to 508C, 508C′ are higher than the at least one predefined segregation distance value and predefined ESN distance value, respectively, for EMI design compliance. This is explained in more detail with reference to FIGS. 3 and 4. Moreover in operation, the verified segregation distances D₁-D₃ and the ESN distances E₁-E₆ are displayed. This is explained in more detail with reference to FIG. 7.

Referring now to FIG. 7, which is a screenshot 700 illustrating segregation distances obtained between the two selected wire harnesses after performing the methods described with reference to FIGS. 1 and 3, according to one embodiment. Particularly, the screenshot 700 illustrates segregations distances D₁-D_{N} between the cutting points 508A, 508A′ to 508N, 508N′, respectively. Further, the screenshot 700 illustrates that the verification of the segregation distances D₁-D_{N} with the predefined segregation distance value is succeeded. Furthermore, the screenshot 700 illustrates, non-compliance segregation distances using dotted arrows and all other segregation distances using line arrows which help to identify the targeted regions where there is a high possibility of EMI occurrence.

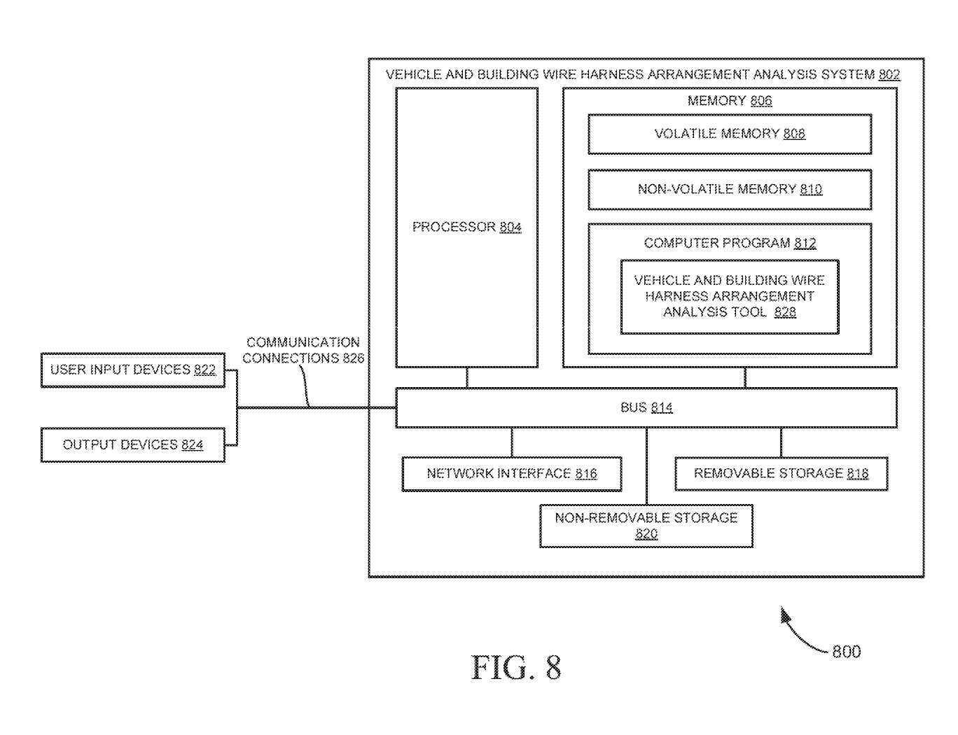

Referring now to FIG. 8, which illustrates a vehicle and building wire harness arrangement analysis system 802 including a vehicle and building wire harness arrangement analysis tool 828 for analyzing arrangement of vehicle and building wire harnesses for EMI, using the process described with reference to FIGS. 1 to 4, according to one embodiment. FIG. 8 and the following discussions are intended to provide a brief, general description of a suitable computing environment in which certain embodiments of the inventive concepts contained herein are implemented.

The vehicle and building wire harness arrangement analysis system 802 includes a processor 804, memory 806, a removable storage 818, and a non-removable storage 820. The vehicle and building wire harness arrangement analysis system 802 additionally includes a bus 814 and a network interface 816. As shown in FIG. 8, the vehicle and building wire harness arrangement analysis system 802 includes access to the computing system environment 800 that includes one or more user input devices 822, one or more output devices 824, and one or more communication connections 826 such as a network interface card and/or a universal serial bus connection.

Exemplary user input devices 822 include a digitizer screen, a stylus, a trackball, a keyboard, a keypad, a mouse and the like. Exemplary output devices 824 include a display unit of the personal computer, a mobile device, and the like. Exemplary communication connections 826 include a local area network, a wide area network, and/or other network.

The memory 806 further includes volatile memory 808 and non-volatile memory 810. A variety of computer-readable storage media are stored in and accessed from the memory elements of the vehicle and building wire harness arrangement analysis system 802, such as the volatile memory 808 and the non-volatile memory 810, the removable storage 818 and the non-removable storage 820. The memory elements include any suitable memory device(s) for storing data and machine-readable instructions, such as read only memory, random access memory, erasable programmable read only memory, electrically erasable programmable read only memory, hard drive, removable media drive for handling compact disks, digital video disks, diskettes, magnetic tape cartridges, memory cards, Memory Sticks™, and the like.

The processor 804, as used herein, means any type of computational circuit, such as, but not limited to, a microprocessor, a microcontroller, a complex instruction set computing microprocessor, a reduced instruction set computing microprocessor, a very long instruction word microprocessor, an explicitly parallel instruction computing microprocessor, a graphics processor, a digital signal processor, or any other type of processing circuit. The processor 804 also includes embedded controllers, such as generic or programmable logic devices or arrays, application specific integrated circuits, single-chip computers, smart cards, and the like.

Embodiments of the present subject matter may be implemented in conjunction with program modules, including functions, procedures, data structures, and application programs, for performing tasks, or defining abstract data types or low-level hardware contexts. Machine-readable instructions stored on any of the above-mentioned storage media may be executable by the processor 804 of the vehicle and building wire harness arrangement analysis system 802. For example, a computer program 812 includes machine-readable instructions capable of analyzing arrangement of vehicle and building wire harness for EMI in the vehicle and building wire harness arrangement analysis system 802, according to the teachings and herein described embodiments of the present subject matter. In one embodiment, the computer program 812 is included on a compact disk-read only memory (CD-ROM) and loaded from the CD-ROM to a hard drive in the non-volatile memory 810. The machine-readable instructions cause the vehicle and building wire harness arrangement analysis system 802 to encode according to the various embodiments of the present subject matter.

As shown, the computer program 812 includes the vehicle and building wire harness arrangement analysis tool 828. For example, the vehicle and building wire harness arrangement analysis tool 828 can be in the form of instructions stored on a non-transitory computer-readable storage medium. The non-transitory computer-readable storage medium having the instructions that, when executed by the vehicle and building wire harness arrangement analysis system 802, causes the vehicle and building wire harness arrangement analysis system 802 to perform the one or more methods described in FIGS. 1 through 7.

In various embodiments, the system and method described in FIGS. 1 through 4 enable analyzing arrangement of vehicle and building wire harnesses for EMI. Although the above subject matter describes analyzing arrangement of vehicle and building wire harnesses for EMI, one can envision that the idea can be applied to any structure including wire harnesses, such as buildings, machine tools, electronic equipment and so on.

Although the present embodiments have been described with reference to specific example embodiments, it will be evident that various modifications and changes may be made to these embodiments without departing from the broader spirit and scope of the various embodiments. Furthermore, the various devices, modules, analyzers, generators, and the like described herein may be enabled and operated using hardware circuitry, for example, complementary metal oxide semiconductor based logic circuitry, firmware, software and/or any combination of hardware, firmware, and/or software embodied in a machine readable medium. For example, the various electrical structure and methods may be embodied using transistors, logic gates, and electrical circuits, such as application specific integrated circuit.

What is claimed is:

1. A method for analyzing arrangement of vehicle and building wire harnesses for electromagnetic interference (EMI), comprising:
receiving at least design data of a first wire harness and a second wire harness and associated electrical structure of the vehicle or building;
applying a plurality of cutting planes to intersect at least the first wire harness and the second wire harness and the associated electrical structure based on the design data;
identifying a respective set of cutting points for each of the plurality of cutting planes, wherein the respective set of cutting points comprises locations where a respective cutting plane intersects at least the first wire harness and the second wire harness and the associated electrical structure; and
measuring a segregation distance between each respective set of cutting points.

2. The method of claim 1, further comprising:
measuring one or more electrical structural network (ESN) distances between the associated electrical structure and the first wire harness and the second wire harness for each respective set of cutting points.

3. The method of claim 1, further comprising:
comparing the segregation distance and ESN distances for each respective set of cutting points to at least one predefined segregation distance value and predefined ESN distance value, respectively; and
verifying whether the segregation distance and the ESN distances for each respective set of cutting points is higher than the at least one predefined segregation distance value and the predefined ESN value, respectively, for EMI design compliance.

4. The method of claim 1, wherein receiving the at least design data of the first wire harness and the second wire harness and the associated electrical structure of the vehicle or building comprises:
receiving three-dimensional model data of the vehicle or building;
creating the first wire harness and/or the second wire harness using a connectivity search of the model data, comprising:
selecting a first wire harness branch and/or second wire harness branch; and
selecting automatically all wire harness branches which are continuously connected to the first wire harness branch and/or the second wire harness branch; and
receiving the first wire harness and/or the second wire harness and the associated electrical structure of the vehicle or building.

5. The method of claim 1, wherein receiving the at least design data of the first wire harness and the second wire harness and the associated electrical structure of the vehicle or building comprises:
receiving three-dimensional model data of the vehicle or building;
creating the first wire harness and/or the second wire harness using a directional search of the model data, comprising:
selecting a first wire harness branch and/or a second wire harness branch; and
selecting automatically one or more wire harness branches for which EMI effects with the first wire harness branch and/or second wire harness branch needs to be analyzed and a deviation angle formed with the first wire harness branch and/or second wire harness branch is of a value lower than a predefined set angle; and
receiving the first wire harness and/or the second wire harness and the associated electrical structure of the vehicle or building.

6. The method of claim 1, wherein receiving the at least design data of the first wire harness and the second wire harness and the associated electrical structure of the vehicle or building comprises:
receiving three-dimensional model data of the vehicle or building;
creating the first wire harness and/or the second wire harness using a manual search of the model data, wherein a user manually selects associated wire harness branches individually; and
receiving the first wire harness and/or the second wire harness and the associated electrical structure of the vehicle or building.

7. The method of claim 1, wherein the plurality of cutting planes intersect at least the first wire harness and the second wire harness according to a predefined resolution.

8. The method of claim 7, wherein the predefined resolution is based on parameters selected from the group consisting of direction of wire harness and curvature of the wire harness.

9. The method of claim 1, wherein the vehicle comprises an aircraft, an automobile, a construction machine or a spacecraft.

10. The method of claim 1, wherein, in receiving, the design data is computer aided design (CAD) data.

11. The method of claim 1, wherein applying the plurality of cutting planes to intersect at least the first wire harness and the second wire harness and the associated electrical structure based on the design data comprises:
applying a plurality of cutting planes to perpendicularly intersect at least the first wire harness and the second wire harness and the associated electrical structure based on the design data.

12. A vehicle and building wire harness arrangement analysis system, comprising:
a processor; and
memory coupled to the processor, wherein the memory includes a vehicle and building wire harness arrangement analysis tool having instructions to:
receive at least design data of a first wire harness and a second wire harness and associated electrical structure of the vehicle or building;
apply a plurality of cutting planes to intersect at least the first wire harness and the second wire harness and the associated electrical structure based on the design data;
identify a respective set of cutting points for each of the plurality of cutting planes, wherein the respective set of cutting points comprises locations where a respective cutting plane intersects at least the first wire harness and the second wire harness and the associated electrical structure; and
measure a segregation distance between each respective set of cutting points.

13. The vehicle and building wire harness arrangement analysis system of claim 12, wherein the vehicle and building wire harness arrangement analysis tool further having instructions to:
measure one or more electrical structural network (ESN) distances between the associated electrical structure and the first wire harness and the second wire harness for each respective set of cutting points.

14. The vehicle and building wire harness arrangement analysis system of claim 12, wherein the vehicle and building wire harness arrangement analysis tool further having instructions to:
compare the segregation distance and ESN distances for each respective set of cutting points to at least one predefined segregation distance value and predefined ESN distance value, respectively; and
verify whether the segregation distance and the ESN distances for each respective set of cutting points is higher than the at least one predefined segregation distance value and the predefined ESN value, respectively, for EMI design compliance.

15. The vehicle and building wire harness arrangement analysis system of claim 12, wherein receiving the at least design data of the first wire harness and the second wire harness and the associated electrical structure of the vehicle or building comprises:
receiving three-dimensional model data of the vehicle or building;
creating the first wire harness and/or the second wire harness using a connectivity search of the model data, comprising:
selecting a first wire harness branch and/or second wire harness branch; and
selecting automatically all wire harness branches which are continuously connected to the first wire harness branch and/or the second wire harness branch; and
receiving the first wire harness and/or the second wire harness and the associated electrical structure of the vehicle or building.

16. The vehicle and building wire harness arrangement analysis system of claim 12, wherein receiving the at least design data of the first wire harness and the second wire harness and the associated electrical structure of the vehicle or building comprises:
receiving three-dimensional model data of the vehicle or building;
creating the first wire harness and/or the second wire harness using a directional search of the model data, comprising:
selecting a first wire harness branch and/or a second wire harness branch; and
selecting automatically one or more wire harness branches for which EMI effects with the first wire harness branch and/or second wire harness branch needs to be analyzed and a deviation angle formed with the first wire harness branch and/or second wire harness branch is of a value lower than a predefined set angle; and
receiving the first wire harness and/or the second wire harness and the associated electrical structure of the vehicle or building.

17. The vehicle and building wire harness arrangement analysis system of claim 12, wherein receiving the at least design data of the first wire harness and the second wire harness and the associated electrical structure of the vehicle or building comprises:
receiving three-dimensional model data of the vehicle or building;
creating the first wire harness and/or the second wire harness using a manual search of the model data, wherein a user manually selects associated wire harness branches individually; and
receiving the first wire harness and/or the second wire harness and the associated electrical structure of the vehicle or building.

18. The vehicle and building wire harness arrangement analysis system of claim 12, wherein the plurality of cutting planes intersect at least the first wire harness and the second wire harness according to a predefined resolution.

19. The vehicle and building wire harness arrangement analysis system of claim 18, wherein the predefined resolution is based on parameters selected from the group consisting of direction of wire harness and curvature of the wire harness.

20. The vehicle and building wire harness arrangement analysis system of claim 12, wherein the vehicle comprises an aircraft, an automobile, a construction machine or a spacecraft.

21. The vehicle and building wire harness arrangement analysis system of claim 12, wherein, in receiving, the design data is computer aided design (CAD) data.

22. The vehicle and building wire harness arrangement analysis system of claim 12, wherein applying the plurality of cutting planes to intersect at least the first wire harness and the second wire harness and the associated electrical structure based on the design data comprises:
applying a plurality of cutting planes to perpendicularly intersect at least the first wire harness and the second wire harness and the associated electrical structure based on the design data.

23. At least one non-transitory computer-readable storage medium for analyzing arrangement of vehicle and building wiring harnesses for electromagnetic interference (EMI) having instructions that, when executed by a computing device, cause the computing device to:
receive at least design data of a first wire harness and a second wire harness and associated electrical structure of the vehicle or building;
apply a plurality of cutting planes to intersect at least the first wire harness and the second wire harness and the associated electrical structure based on the design data;
identify a respective set of cutting points for each of the plurality of cutting planes, wherein the respective set of cutting points comprises locations where a respective cutting plane intersects at least the first wire harness and the second wire harness and the associated electrical structure; and
measure a segregation distance between each respective set of cutting points.

24. The at least one non-transitory computer-readable storage medium of claim 23, further comprising:
measuring one or more electrical structural network (ESN) distances between the associated electrical structure and the first wire harness and the second wire harness for each respective set of cutting points.

25. The at least one non-transitory computer-readable storage medium of claim 23, further comprising:
comparing the segregation distance and ESN distances for each respective set of cutting points to at least one predefined segregation distance value and predefined ESN distance value, respectively; and
verifying whether the segregation distance and the ESN distances for each respective set of cutting points is higher than the at least one predefined segregation distance value and the predefined ESN value, respectively, for EMI design compliance.

26. The at least one non-transitory computer-readable storage medium of claim 23, wherein receiving the at least design data of the first wire harness and the second wire harness and associated the electrical structure of the vehicle or building comprises:
receiving three-dimensional model data of the vehicle or building;
creating the first wire harness and/or the second wire harness using a connectivity search of the model data, comprising:
selecting a first wire harness branch and/or second wire harness branch; and
selecting automatically all wire harness branches which are continuously connected to the first wire harness branch and/or the second wire harness branch; and
receiving the first wire harness and/or the second wire harness and the associated electrical structure of the vehicle or building.

27. The at least one non-transitory computer-readable storage medium of claim 23, wherein receiving the at least design data of the first wire harness and the second wire harness and the associated electrical structure of the vehicle or building comprises:
receiving three-dimensional model data of the vehicle or building;
creating the first wire harness and/or the second wire harness using a directional search of the model data, comprising:
selecting a first wire harness branch and/or a second wire harness branch; and
selecting automatically one or more wire harness branches for which EMI effects with the first wire harness branch and/or second wire harness branch needs to be analyzed and a deviation angle formed with the first wire harness branch and/or second wire harness branch is of a value lower than a predefined set angle; and
receiving the first wire harness and/or the second wire harness and the associated electrical structure of the vehicle or building.

28. The at least one non-transitory computer-readable storage medium of claim 23, wherein receiving the at least design data of the first wire harness and the second wire harness and the associated electrical structure of the vehicle or building comprises:
receiving three-dimensional model data of the vehicle or building;
creating the first wire harness and/or the second wire harness using a manual search of the model data, wherein a user manually selects associated wire harness branches individually; and
receiving the first wire harness and/or the second wire harness and the associated electrical structure of the vehicle or building.
